(19) United States
(12) Patent Application Publication
(10) Pub. No.: US 2006/0273391 A1
(43) Pub. Date: Dec. 7, 2006

(54) CMOS devices for low power integrated circuits

(76) Inventors: Carlos H. Diaz, Mountain View, CA (US); Mi-Chang Chang, Hsin-Chu (TW)

Correspondence Address: SLATER & MATSIL, L.L.P., 17950 PRESTON ROAD, SUITE 1000, DALLAS, TX, 75252, US

(21) Appl. No.: 11/142,214

(22) Filed: Jun. 1, 2005

(51) Int. Cl. H01L 29/76

(52) U.S. Cl. 257/335; 257/336; 257/342; 257/344; 257/408

(57) ABSTRACT

A preferred embodiment of the invention provides a semiconductor fabrication method. An embodiment comprises forming a MOS device and thermally oxidizing the MOS device to form a gate dielectric substantially thicker at a gate dielectric edge than that at a gate dielectric center. Embodiments further comprise performing a source/drain ion implant to form an asymmetric source/drain, wherein the source region includes a high leakage source junction, and wherein the drain region includes a low leakage drain junction. Other embodiments of the invention comprise a MOS device formed in a semiconductor substrate, wherein the device has improved resistance to floating body effects. Still other embodiments include a CMOS device for low power integrated circuits.

### TECHNICAL FIELD

This invention relates generally to semiconductor devices, and, more particularly, to integrated circuits and to methods for controlling off-state leakage currents.

### BACKGROUND

The need for overall performance and power improvements as well as the integration density drives the CMOS device size reduction. This in turn places a fundamental requirement on the depth, abruptness, and resistance of the drain and source junctions in NMOS and PMOS devices. The more abrupt and low-resistance junctions increase the device off-state leakage current and power thus creating a barrier for the continued scaling of CMOS devices for low standby power ICs used in mobile and other application segments.

One approach to improve DRAM data retention time is by forming pass transistors with asymmetric source and drain structures as reported by Shito et al., in U.S. Pat. No. 6,238,967. However, this approach is limited to DRAM applications and does not address the low leakage-power requirements of non-DRAM technologies and applications. Another approach reported by Burr et al., in U.S. Pat. No. 5,780,912 relies on asymmetric devices to form low threshold voltage devices suitable for low active-power circuits. Those devices are said to have on-state to off-state drain-source current ratios of no more than 10⁵. This approach does not apply to a majority of state-of-the art CMOS devices, particularly those devices used for low standby leakage-power requirements where the on-off ratios can be as high as 10⁶ or more. Furthermore, the engineering of those asymmetric devices is not specially tailored to reduce drain leakage as required by the mobile application segment.

In light of problems such as these, there remains a need for improved structures and methods for reducing off-state leakage currents in non-DRAM semiconductor devices.

### SUMMARY OF THE INVENTION

These and other problems are generally solved or circumvented, and technical advantages are generally achieved by preferred embodiments of the present invention that provides methods and structure for reducing the off-state leakage currents in semiconductor devices.

Embodiments of the invention provide a semiconductor device and its fabrication method. An embodiment comprises forming a MOS device in a substrate. The MOS device includes a source region, a drain region, a channel region between the source and drain regions, a gate dielectric over the channel region, and a gate electrode over the gate dielectric. Preferably, the substrate includes a dopant concentration of a first conductivity type, and the source and drain regions include a dopant concentration of the second conductivity type. An embodiment of the invention includes different pocket or halo implants abutting the source and drain regions. In another embodiment, the drain region includes a graded drain junction.

An embodiment of the invention further includes an asymmetric halo region having a dopant concentration of the first conductivity type, proximate the channel region, and abutting the source and drain regions. Preferably, the asymmetric halo region underlies a source and drain extension of the source and drain regions, respectively. In embodiments, the asymmetric halo region abutting the source region comprises a high leakage junction. Preferably, the high leakage junction includes a first conductivity type dopant about 1E18 to 1E19 cm-3. In other embodiments, the asymmetric halo region abutting the drain region comprises a low leakage junction. Preferably, the low leakage junction includes a halo or pocket region of first conductivity type dopant with concentration less than about 1E18 cm-3.

In still another embodiment, the asymmetric halo region includes a low leakage drain junction substantially without pocket or halo implants. In another embodiment of the invention, the gate dielectric is substantially thicker at its edges than at its center, preferably at least about 20% thicker.

Other embodiments of the invention provide a semiconductor device, wherein the device comprises a low power circuit. In a preferred embodiment, the device comprises a low-standby power device. The device includes an active device, such as a non-DRAM device, in a substrate, an asymmetric halo region, and gate dielectric having areas of different thickness.

One embodiment includes a current flow controlling the device between power/ground supplies and logic/analog circuitry, wherein the current flow controlling device includes an asymmetric halo region in a substrate. In preferred embodiments, the device including an asymmetric halo region in the substrate is formed according to embodiments of the invention described herein.

Other embodiments include a plurality of current flow controlling devices that control the power supply which is electrically connected with gate array or standard cell logic circuit. The plurality of devices comprise a plurality of gates with the same longitudinal gate orientation in the die or integrated circuit.

Other embodiments include a plurality of current flow controlling devices that control the ground supply which is electrically connected with gate array or standard cell logic circuit. The plurality of devices comprise a plurality of gates with the same longitudinal gate orientation in the die/integrated circuit.

Other embodiments include gate arrays with restricted gate orientation placement in the die/integrated circuit. Other embodiments further comprise standard cells with restricted gate orientation placement in the die/integrated circuit.

Additional features and advantages of embodiments of the invention will be described hereinafter, which form the subject of the claims of the invention. It should be appreciated by those skilled in the art that the specific embodiments disclosed might be readily utilized as a basis for modifying or designing other structures or processes for carrying out the purposes of the present invention. It should also be realized by those skilled in the art that such equivalent constructions and variations on the example embodiments described do not depart from the spirit and scope of the invention as set forth in the appended claims.

### DESCRIPTION OF THE DRAWINGS

For a more complete understanding of the present invention, and the advantages thereof, reference is now made to the following descriptions taken in conjunction with the accompanying drawings, in which:

FIGS. 1-7 are cross-sectional views of the manufacture of a device according to embodiments of the invention; and

FIG. 8 is a schematic illustration of a low-standby power circuit according to embodiments of the invention;

Corresponding numerals and symbols in the different figures generally refer to corresponding parts unless otherwise indicated. The figures are drawn to clearly illustrate the relevant aspects of the preferred embodiments and are not necessarily drawn to scale. To more clearly illustrate certain embodiments, a letter indicating variations of the same structure, material, or process step may follow a figure number.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention. The intermediate stages of manufacturing a preferred embodiment of the present invention are illustrated throughout the various views and illustrative embodiments of the present invention. To more clearly illustrate certain embodiments, a letter indicating variations of the same structure, material, or process step may follow a figure number.

This invention relates generally to semiconductor device fabrication and more particularly to structures and methods for devices formed on semiconductor substrates. The present invention will now be described with respect to preferred embodiments in a specific context, namely the creation of a MOSFET device. It is believed that embodiments of this invention are particularly advantageous when used in this process. It is believed that embodiments described herein will benefit other applications not specifically mentioned. Therefore, the specific embodiments discussed are merely illustrative of specific ways to make and use the invention, and do not limit the scope of the invention.

Turning to FIG. 1, there is illustrated an intermediate semiconductor device according to embodiments of the invention. FIG. 1 shows a cross sectional view of a substrate 25, which may be formed according to conventional methods. The substrate 25 may comprise a conventional silicon on insulator (SOI) structure or bulk wafers or substrates such as Si, Ge, SiGe, GaAs, GaAlAs, InP, GaN, and/or combinations thereof. Continuing with FIG. 1, there is shown the substrate 25 within which an active device region 112 is formed. Within the active device region 112 is formed a gate oxide dielectric layer 116 over which is formed a patterned polycrystalline silicon gate electrode layer 118.

With respect to the substrate 25 shown in FIG. 1, it may be of either polarity of doping, since both p-type and n-type silicon regions may be employed to form the corresponding polarity FET devices employed in microelectronics fabrications and circuits. Preferably, the substrate 25 is a single crystal silicon having a (100) crystalline orientation.

In alternative embodiments (not illustrated), the substrate 25 orientation and charge carrier channel orientation may be selected with a view towards optimizing the appropriate charge carrier mobility. This includes but is not limited to using SOI hybrid orientation and/or any other hybrid-orientation substrates.

With respect to the silicon active device region 112 shown in FIG. 1, which may include a MOS device 104, formed therein is the gate dielectric layer 116 of silicon oxide dielectric material. Preferably the gate dielectric layer 116 is formed by thermal or plasma-assisted oxidation of the silicon substrate 25. The gate dielectric layer 116 can also be any higher dielectric constant material (high-k) deposited by chemical or atomic-layer deposition methods. The gate dielectric can also be a combination of silicon oxide, silicon oxy-nitride, and/or high-k materials formed prior to gate electrode formation.

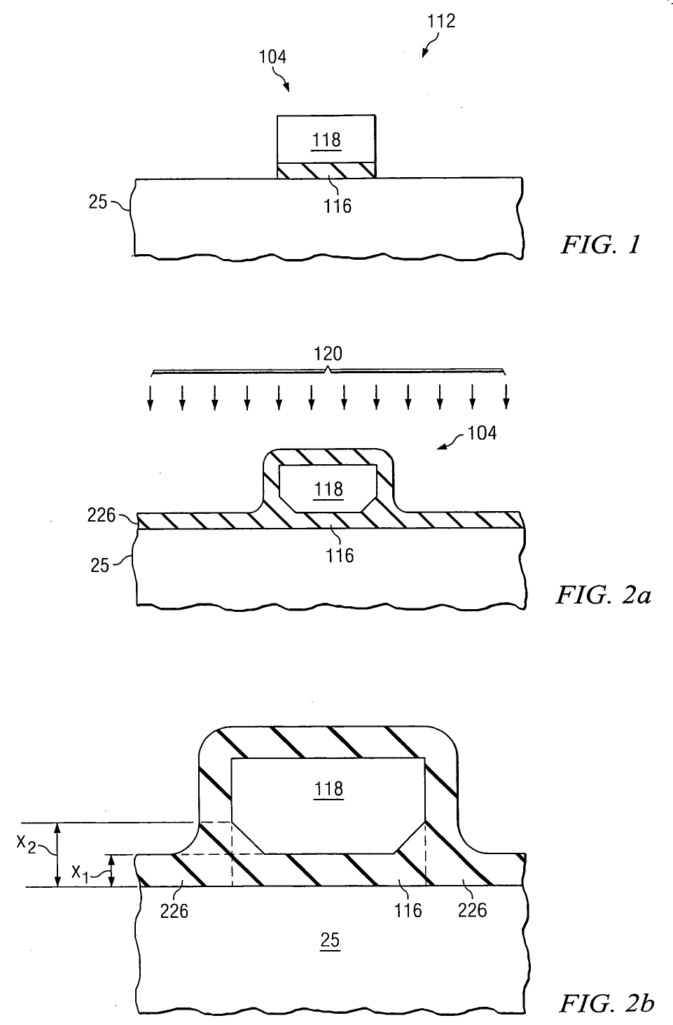

The gate electrode 118 can also be formed by single or multiple stacks of metal gates deposited and patterned by methods and materials known in the art of microelectronics fabrication. Referring now more particularly to FIG. 2a, there is shown a schematic cross-sectional diagram illustrating the results of the optional further processing of the MOS device 104 whose schematic cross-sectional diagram is shown in FIG. 1 in accordance with embodiments of the present invention. Shown in FIG. 2a is a microelectronics fabrication otherwise equivalent to the microelectronics fabrication shown in FIG. 1, but where there has been thermal oxidation of at least the gate electrode 118 and the gate dielectric 116 in an oxidizing environment 120 to form a thicker gate dielectric layer 226 at the edge of gate electrode layer 118.

FIG. 2b is a cross sectional and enlarged view of the gate dielectric 116 and adjacent regions. According to embodiments of the invention, the above-described thermal oxidation process causes the gate dielectric layer 116 to be substantially thicker at the gate dielectric 116 edges than at the gate dielectric 116 center. In FIG. 2b, the vertical dashed lines illustrate the edges of the gate dielectric 116. As shown in FIG. 2b, the dielectric edge thickness, x₂, is substantially thicker than the center dielectric thickness, x₁. Preferably, x₂ is at least about 20% larger than x₁.

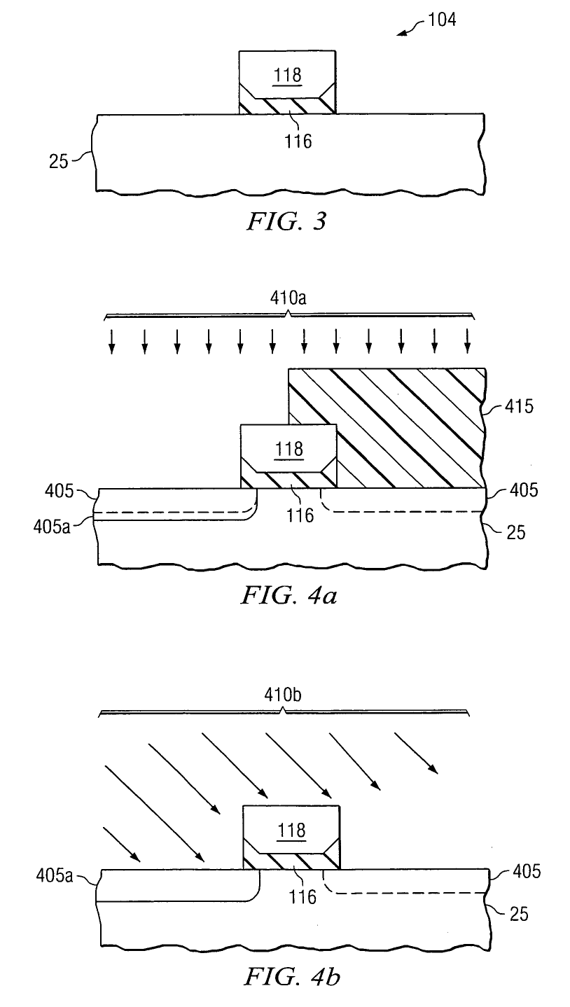

Turning now to FIG. 3, there is shown a schematic cross-sectional diagram illustrating the results of further optional processing of the microelectronics fabrication whose schematic cross-sectional diagram is shown in FIG. 2. Shown in FIG. 3 is the MOS device 104 of FIG. 2, but where the thermal silicon oxide layer 226 is etched away by methods and chemicals known in the art of microelectronics. Preferably, the thermal silicon oxide layer is etched back to expose the silicon surface.

The initiation of the multi-component profile is used to create the LDD region, the pocket or halo implant region. In the next step, an implant step is performed to create optional symmetric pockets/halos 405 of first conductivity type in the source/drain regions. The implant dose used will result in optional symmetric pocket regions 405 shown in FIG. 4a that are generally greater in dopant concentration than the dopant concentration of the substrate 25. The objective of the optional symmetric pocket region, with a specific dopant concentration, is to limit the extent of the depletion region formed between the source/drain and substrate regions.

In preferred embodiments, an asymmetric device is desired to reduce drain junction leakage and consequently the device off-state leakage current. Turning to FIG. 4a, this asymmetric device has asymmetric pocket or halo implants region 405a essentially only on the source side of the channel. One method of formation of the asymmetric devices relies on an asymmetrical photoresist 415 as a mask to protect the drain side from the pocket or halo implant 410a as shown in FIG. 4a.

After the first implantation procedure featuring the optional symmetric pocket/halo implant 405; a second, and asymmetric, implantation procedure 410a of first conductivity type is performed to form the asymmetric pocket or halo implant region 405a. After this implant, photoresist shape 415 is removed using plasma oxygen ashing and careful wet cleans, followed by the formation of the LDD regions, on both sides of the gate structure, in regions of the semiconductor substrate not covered by gate electrode 118.

Another method of forming asymmetrical pocket/halo regions involves implanting the pocket and halos by properly positioning the wafer in the implantation chamber so implant ions 410b strike only the substrate from one side of the gate (i.e. the source side). This is to form the asymmetric pocket or halo region 405a of first conductivity type as illustrated in FIG. 4b.

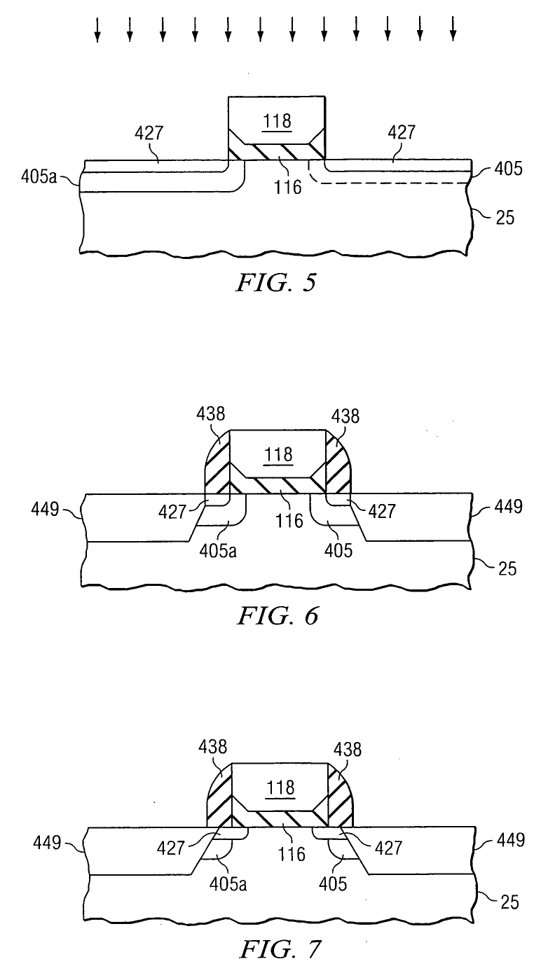

Turning now to FIG. 5, a third ion implantation procedure is used to create LDD or extension regions 427. Implantation creates LDD region 427 of second conductivity type, in top portions of optional pocket regions 405 and asymmetrical pocket or halo region 405a, and in areas of the substrate 25 not covered by the gate electrode 118.

Turning now to FIG. 6, an insulator layer such as silicon oxide, silicon nitride, or a combination of both, is next deposited via LPCVD or via plasma enhanced chemical vapor deposition (PECVD) procedures. An anisotropic reactive ion etching procedure is used to define insulator spacers 43 8, located on the sides of gate electrode 118 and the gate dielectric 116. This is schematically shown in FIG. 6.

A fourth ion implantation procedure is next performed, resulting in the formation of heavily doped source/drain region 449 of second conductivity type, in areas of substrate 25, not covered by the gate electrode 118, or by the insulator spacers 438. This is also illustrated schematically in FIG. 6.

Turning now to FIG. 7, an anneal procedure is used to activate the dopants and to anneal implant damage. This anneal procedure relies on either conventional furnace procedures, a rapid thermal anneal procedure, a flash lamp anneal procedure, a laser anneal procedure, or any combination of those procedures. Together 405 and 405a provide the asymmetric pocket or halo implants according to embodiments of the invention. Embodiments described herein include high source leakage characteristics and low leakage drain characteristics that advantageously ameliorate floating body effects in devices formed on SOI substrates. The low drain leakage current characteristics are fundamental to low stand-by power or low leakage-power applications.

An embodiment of the invention further includes an asymmetric halo region having a dopant concentration of the first conductivity type, proximate the channel region, and abutting the source and drain regions. Preferably, the asymmetric halo region underlies a source and drain extension of the source and drain regions, respectively. In embodiments, the asymmetric halo region abutting the source region comprises a high leakage junction. Preferably, the high leakage junction includes a first conductivity type dopant about 1E18 to 1E19 cm-3. In other embodiments, the asymmetric halo region abutting the drain region comprises a low leakage junction. Preferably, the low leakage junction includes a first conductivity type dopant about less than about 1E18 cm-3.

Still other embodiments of the invention comprise a low-standby power device. The devices comprises a substrate and an active device in the substrate. Preferably, the active device comprises a source, a drain, and a gate. The substrate further comprises an asymmetric halo region in the substrate, and a gate dielectric over the substrate, wherein the optional gate dielectric thickness at the gate edge is substantially thicker than the gate dielectric thickness at a gate center. Preferably, the device comprises a non-DRAM cell device. Preferably, the asymmetric halo or pocket region comprises a low leakage drain junction substantially without pocket or halo implants. In other embodiments, the asymmetric halo region comprises a low leakage drain junction comprising a graded drain junction. Preferably, the low leakage drain junction comprises an implant concentration less than 1E18 cm-3 of first conductivity type to form an asymmetric pocket or halo under a drain extension side. In other embodiments, the asymmetric halo region comprises a high leakage source junction with pocket or halo implants. In preferred embodiments, the high leakage source junction comprises an implant concentration between 1E18 and 1E19 cm-3 of first conductivity type to form an asymmetric pocket or halo under a source extension side. In alternative embodiments, the asymmetric halo region comprises a different extension depth in the source and in the drain.

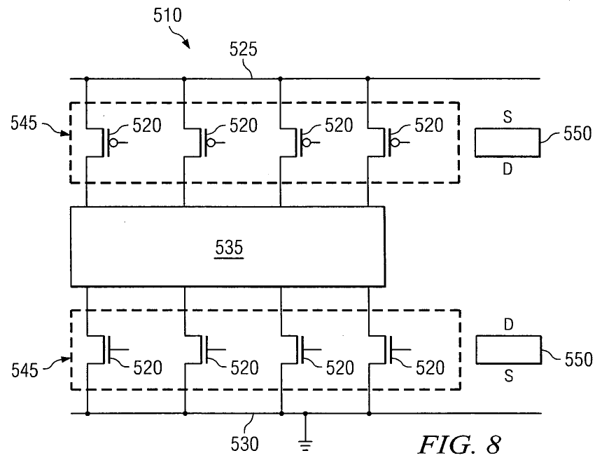

In accordance with embodiments of the invention previously described, still other embodiments provide for CMOS devices 5 1 0 for low power integrated circuits as shown in FIG. 8. More particularly, embodiments comprise a current flow-controlling device 520 between power 525 and ground 530 supplies and logic/analog circuits 535 arranged such as illustrated in FIG. 8. In preferred embodiments, the current flow-controlling device 520 comprises an asymmetric halo MOS device fabricated according to embodiments described herein.

In other embodiments, the CMOS devices for low power integrated circuits comprise a plurality 545 of current flow controlling devices. The plurality 545 may be for controlling a power supply 525 that is electrically connected to gate arrays or standard cell logic circuits. In other embodiments, the plurality 545 may be for controlling a ground supply 530 that is electrically connected to gate arrays or standard cell logic circuits. In order to improve and simplify the manufacturing procedure of such arrays, the plurality of current flow controlling devices comprise a plurality of gates with the same longitudinal gate orientation 550, as illustrated in FIG. 8. Preferably, the orientation 550 includes embodiments illustrated in FIG. 7. More preferably, the orientation 550 includes a low leakage drain and a high leakage source, wherein the high leakage source includes an asymmetric halo region.

Other embodiments of the invention comprise a low-standby power circuit. The circuit includes a current flow controlling device between a power/ground supply and a logic/analog circuit, wherein the current flow controlling device comprises an asymmetric halo region in a substrate. Preferably, the current flow-controlling device comprises a gate dielectric over the substrate, where the gate dielectric thickness at a gate edge is substantially thicker than the gate dielectric thickness at a gate center. In alternate embodiments, the device further comprises gate arrays with restricted gate orientation placement. Other embodiments comprise standard-cells with restricted gate orientation placement. In still other embodiments, the device comprises a plurality of current controlling devices, wherein the plurality of current controlling devices controls a power supply connected to a gate array or standard cell logic circuit, and wherein the plurality of current controlling devices comprise a plurality of gates with a same longitudinal gate orientation. Other embodiments further comprise a plurality of current controlling devices, wherein the plurality of current controlling devices controls a ground connected to a gate array or standard cell logic circuit, and wherein the plurality of current controlling devices comprise a plurality of gates with a same longitudinal gate orientation.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A low-standby power device comprising:
a substrate;
an active device in the substrate, wherein the active device comprises a source, a drain, and a gate;
an asymmetric halo region in the substrate; and
a gate dielectric over the substrate, wherein a gate dielectric thickness at a gate edge is substantially thicker than the gate dielectric thickness at a gate center.

2. The device of claim 1, wherein the device comprises a non-DRAM cell device.

3. The device of claim 1, wherein the substrate comprises silicon.

4. The device of claim 1, wherein the substrate comprises germanium.

5. The device of claim 1, wherein the substrate comprises silicon germanium.

6. The device of claim 1, wherein the substrate comprises silicon on insulator (SOI).

7. The device of claim 1, wherein the asymmetric halo region comprises a low leakage drain junction substantially without pocket or halo implants.

8. The device of claim 1, wherein the asymmetric halo region comprises a low leakage drain junction comprising a graded drain junction.

9. The device of claim 8, wherein the low leakage drain junction comprises an implant concentration less than 1E18 cm-3 under a drain extension side.

10. The device of claim 1, wherein the asymmetric halo region comprises a high leakage source junction with pocket or halo implants.

11. The device of claim 10, wherein the high leakage source junction comprises a pocket implant region with a concentration between 1E18 and 1E19 cm-3 under a source extension side.

12. The device of claim 10, wherein the high leakage source junction comprises a halo implant region with a concentration between 1E18 and 1E19 cm-3 under a source extension side.

13. The device of claim 1, wherein the asymmetric halo region comprises a different extension depth in the source and in the drain.

14. The device of claim 1, wherein the gate edge thickness is greater than 20% thicker than the gate center thickness.

15. A low-standby power circuit comprising: a current flow controlling device between a power/ground supply and a logic/analog circuit, wherein the current flow controlling device comprises an asymmetric halo region in a substrate.

16. The circuit of claim 15, wherein the current flow controlling device comprises a gate dielectric over the substrate, where a gate dielectric thickness at a gate edge is substantially thicker than the gate dielectric thickness at a gate center.

17. The circuit of claim 15, further comprising gate arrays with restricted gate orientation placement.

18. The circuit of claim 15, further comprising standard-cells with restricted gate orientation placement.

19. The circuit of claim 15, further comprising a plurality of the current flow controlling devices; wherein the plurality of current flow controlling devices controls the power supply that is electrically connected to gate arrays or standard cell logic circuits.

20. The circuit of claim 15, further comprising a plurality of the current flow controlling devices; wherein the plurality of current flow controlling devices controls the ground supply that is electrically connected to gate arrays or standard cell logic circuits.

21. The circuit of claim 15, further comprising a plurality of the current flow controlling devices; wherein the plurality of current flow controlling devices have a same longitudinal gate orientation within a die or an integrated circuit.
